(19) United States
(12) Patent Application Publication
(10) Pub. No.: US 2025/0275389 A1
(43) Pub. Date: Aug. 28, 2025

(54) DISPLAY PANEL, METHOD OF MANUFACTURING THE SAME, AND DISPLAY DEVICE

(71) Applicants: Chengdu BOE Optoelectronics Technology Co., Ltd., Chengdu (CN); BOE Technology Group Co., Ltd., Beijing (CN)

(72) Inventors: Qian Li, Beijing (CN); Ziyang Yu, Beijing (CN)

(21) Appl. No.: 18/710,285

(22) PCT Filed: May 17, 2023
(86) PCT No.: PCT/CN2023/094687

§ 371 Date: May 15, 2024

(51) Int. Cl. H10K 59/131; H10K 59/12; H10K 71/60

(52) U.S. Cl. CPC H10K 59/131; H10K 59/1201; H10K 71/60

(57) ABSTRACT

A display panel, a method of manufacturing the same, and a display device are provided. The display panel includes: a base substrate; a plurality of first electrode patterns, second electrode patterns and light emitting layer patterns arranged in display region of the base substrate; a pixel defining layer including a plurality of pixel openings at least partially exposing the plurality of first electrode patterns respectively; the plurality of light emitting layer patterns are at least partially located in the pixel openings respectively; orthographic projections of at least some of the second electrode patterns on base substrate are spaced apart from each other in first direction and second direction; and a plurality of electrode wires located in at least one conductive layer between the base substrate and a layer where the second electrode patterns are located, at least one electrode wire is electrically connected to second electrode pattern.

### CROSS-REFERENCE TO RELATED APPLICATION

This application is a Section 371 National Stage Application of International Application No. PCT/CN2023/094687, filed on May 17, 2023, entitled “DISPLAY PANEL, METHOD OF MANUFACTURING THE SAME, AND DISPLAY DEVICE”, the content of which is hereby incorporated by reference in its entirety.

### TECHNICAL FIELD

The present disclosure relates to the field of display technology, and in particular, to a display panel, a method of manufacturing the same, and a display device.

### BACKGROUND

Organic light emitting diode (OLED) display devices are self-luminous devices with advantages of high response, high contrast, and flexibility, and have been widely used in the field of display. In order to achieve a light transmittance of an OLED, a top emitting electrode at a light exit surface of a top emitting OLED needs to have a good light transmittance. Generally speaking, a top emitting electrode is provided all over the surface and is made of indium tin oxide, indium zinc oxide and other materials, and the top emitting electrode is connected with a power supply wire VSS. Since the top emitting electrode is provided all over the surface and the top emitting electrode has a small thickness in order to improve the light transmittance, the top emitting electrode may have a high impedance. A voltage drop between a side region and a center region at an overlap with the VSS is great, which may lead to a poor brightness uniformity of an OLED product. This may become particularly obvious as an area of an OLED display device increases.

The above information disclosed in this section is just for understanding of the background of technical concepts of the present disclosure. Therefore, the above information may contain information that does not constitute a related art.

### SUMMARY

To address at least one aspect of the aforementioned problems, the embodiments of the present disclosure provide a display panel, a method of manufacturing the same, and a display device, which may at least reduce a voltage drop of the display panel and improve a display uniformity.

In an aspect, a display panel is provided, including: a base substrate, including a display region and a peripheral region located at least on a first side of the display region: a plurality of first electrode patterns, where the plurality of first electrode patterns are arranged in an array in a first direction and a second direction in the display region of the base substrate: a pixel defining layer located on a side of a layer where the plurality of first electrode patterns are located away from the base substrate, where the pixel defining layer includes a plurality of pixel openings, and the plurality of first electrode patterns are at least partially exposed by the plurality of pixel openings respectively; a plurality of light emitting layer patterns arranged in an array in the first direction and the second direction in the display region of the base substrate, where the plurality of light emitting layer patterns are at least partially located in the plurality of pixel openings respectively: a plurality of second electrode patterns located on a side of a layer where the plurality of light emitting layer patterns are located away from the base substrate, where the plurality of second electrode patterns are arranged in an array in the first direction and the second direction in the display region of the base substrate, and orthographic projections of at least some of the plurality of second electrode patterns on the base substrate are spaced apart from each other in the first direction and the second direction; and a plurality of electrode wires located in at least one conductive layer between the base substrate and a layer where the plurality of second electrode patterns are located, where at least one electrode wire is electrically connected to at least one second electrode pattern through a second electrode via hole, where an orthographic projection of the second electrode via hole on the base substrate is located in the display region.

In some exemplary embodiments of the present disclosure, the display panel includes a plurality of pixel units arranged in an array in the first direction and the second direction in the display region of the base substrate, and at least one pixel unit includes a plurality of sub-pixels: at least one pixel unit includes at least one second electrode pattern and at least one second electrode via hole: and/or at least one pixel unit includes at least two second electrode patterns and at least two second electrode via holes.

In some exemplary embodiments of the present disclosure, in a same pixel unit, at least two sub-pixels share a second electrode pattern and a second electrode via hole, and the other sub-pixel has a separate second electrode pattern and a separate second electrode via hole.

In some exemplary embodiments of the present disclosure, the plurality of sub-pixels of at least one pixel unit share a second electrode pattern and a second electrode via hole.

In some exemplary embodiments of the present disclosure, the plurality of sub-pixels of at least one pixel unit have respective second electrode patterns and respective second electrode via holes.

In some exemplary embodiments of the present disclosure, at least one pixel unit includes a first sub-pixel, a second sub-pixel and a third sub-pixel, and the plurality of electrode wires include a first electrode wire, a second electrode wire and a third electrode wire: the shared second electrode pattern is electrically connected to the first electrode wire and the second electrode wire through the shared second electrode via hole: the second electrode pattern of the other sub-pixel is electrically connected to the third electrode wire through the separate second electrode via hole: the first electrode wire and the second electrode wire are connected to a same voltage signal, and the first electrode wire and the third electrode wire are connected to different voltage signals.

In some exemplary embodiments of the present disclosure, the plurality of sub-pixels of at least one pixel unit include a first sub-pixel, a second sub-pixel and a third sub-pixel, and the plurality of electrode wires include a first electrode wire, a second electrode wire and a third electrode wire: the second electrode pattern of the first sub-pixel is electrically connected to the first electrode wire through the second electrode via hole, the second electrode pattern of the second sub-pixel is electrically connected to the second electrode wire through the second electrode via hole, and the second electrode pattern of the third sub-pixel is electrically connected to the third electrode wire through the second electrode via hole; at least two of the first electrode wire, the second electrode wire and the third electrode wire are connected to different voltage signals.

In some exemplary embodiments of the present disclosure, at least one pixel unit includes a first sub-pixel, a second sub-pixel and a third sub-pixel, and the plurality of electrode wires include a first electrode wire, a second electrode wire and a third electrode wire: the shared second electrode pattern is electrically connected to the first electrode wire, the second electrode wire and the third electrode wire through the shared second electrode via hole: the first electrode wire, the second electrode wire and the third electrode wire are connected to a same voltage signal.

In some exemplary embodiments of the present disclosure, the display panel includes: a buffer layer provided on the base substrate: a semiconductor layer provided on a side of the buffer layer away from the base substrate: a first insulating layer provided on a side of the semiconductor layer away from the base substrate: a first conductive layer provided on a side of the first insulating layer away from the base substrate: a second insulating layer provided on a side of the first conductive layer away from the base substrate: a second conductive layer provided on a side of the second insulating layer away from the base substrate; a third insulating layer provided on a side of the second conductive layer away from the base substrate: a third conductive layer provided on a side of the third insulating layer away from the base substrate: and a fourth insulating layer provided on a side of the third conductive layer away from the base substrate, where each of an orthographic projection of the buffer layer on the base substrate, an orthographic projection of the first insulating layer on the base substrate, an orthographic projection of the first conductive layer on the base substrate, an orthographic projection of the second insulating layer on the base substrate, an orthographic projection of the second conductive layer on the base substrate and an orthographic projection of the third insulating layer on the base substrate overlaps partially with an orthographic projection of the second electrode via hole on the base substrate.

In some exemplary embodiments of the present disclosure, the second electrode via hole penetrates through a portion of the fourth insulating layer and a portion of the pixel defining layer: and the electrode wire has a first portion and a second portion at the second electrode via hole, the first portion of the electrode wire is located in the third conductive layer, and the second portion of the electrode wire is located in the layer where the first electrode patterns are located.

In some exemplary embodiments of the present disclosure, the display panel further includes: a fifth insulating layer provided between the third conductive layer and the fourth insulating layer: and a fourth conductive layer provided between the fifth insulating layer and the fourth insulating layer, where each of the orthographic projection of the buffer layer on the base substrate, the orthographic projection of the first insulating layer on the base substrate, the orthographic projection of the first conductive layer on the base substrate, the orthographic projection of the second insulating layer on the base substrate, the orthographic projection of the second conductive layer on the base substrate, the orthographic projection of the third insulating layer on the base substrate, an orthographic projection of the third conductive layer on the base substrate and an orthographic projection of the fifth insulating layer on the base substrate overlaps partially with the orthographic projection of the second electrode via hole on the base substrate.

In some exemplary embodiments of the present disclosure, the second electrode via hole penetrates through a portion of the fourth insulating layer and a portion of the pixel defining layer: and the electrode wire has a first portion and a second portion at the second electrode via hole, the first portion of the electrode wire is located in the fourth conductive layer, and the second portion of the electrode wire is located in the layer where the first electrode patterns are located.

In some exemplary embodiments of the present disclosure, first portions of the electrode wires are spaced apart in the second electrode via hole, and the second portions of the electrode wires are continuously arranged in the second electrode via hole.

In some exemplary embodiments of the present disclosure, the electrode wire includes a first electrode sub-wire and a second electrode sub-wire in the fourth conductive layer, a main body of the first electrode sub-wire extends in the first direction, and a main body of the second electrode sub-wire extends in the second direction: the first electrode sub-wire and the second electrode sub-wire intersect at least in the second electrode via hole.

In some exemplary embodiments of the present disclosure, the display panel further includes a data signal line configured to provide a data signal to the pixel unit, the data signal line is located in the third conductive layer, and a main body of the data signal line extends in the second direction: an orthographic projection of the second electrode sub-wire on the base substrate overlaps at least partially with an orthographic projection of the data signal line on the base substrate.

In some exemplary embodiments of the present disclosure, the display panel further includes a voltage signal line configured to provide a voltage signal to the first electrode pattern of the pixel unit: and the voltage signal line includes a first voltage signal sub-line and a second voltage signal sub-line, a main body of the first voltage signal sub-line extends in the first direction, and a main body of the second voltage signal sub-line extends in the second direction.

In some exemplary embodiments of the present disclosure, the display panel includes a plurality of second voltage signal sub-lines, at least one second voltage signal sub-line is located in the third conductive layer, and at least another second voltage signal sub-line is located in the fourth conductive layer: an orthographic projection of the at least one second voltage signal sub-line in the third conductive layer on the base substrate is spaced apart from an orthographic projection of the second electrode sub-wire on the base substrate at least in the second electrode via hole, and an orthographic projection of the at least another second voltage signal sub-line in the fourth conductive layer on the base substrate is spaced apart from the orthographic projection of the second electrode sub-wire on the base substrate.

In some exemplary embodiments of the present disclosure, the at least another second voltage signal sub-line located in the fourth conductive layer extends through a gap between first portions of the electrode wires in the second electrode via hole.

In some exemplary embodiments of the present disclosure, the display panel includes a plurality of second electrode sub-wires, at least one second electrode sub-wire includes a winding portion, and the at least one second electrode sub-wire extends through a region where the first electrode pattern is located through the winding portion: and at least another second electrode sub-wire is disconnected in the region where the first electrode pattern is located.

In some exemplary embodiments of the present disclosure, the winding portion includes a first winding sub-portion, a second winding sub-portion and a third winding sub-portion, the first winding sub-portion and the third winding sub-portion extend in the first direction, and the second winding sub-portion extends in the second direction: for a same second electrode sub-wire, an orthotropic projection of the second winding sub-portion in the region where the first electrode pattern is located on the base substrate is closer to an edge of the first electrode pattern than an orthotropic projection of a portion of the second electrode sub-wire outside the region where the first electrode pattern is located on the base substrate.

In some exemplary embodiments of the present disclosure, the first electrode pattern includes a first electrode body portion and a first electrode connecting portion, the display panel further includes a first electrode via hole, and an orthographic projection of the first electrode connecting portion on the base substrate overlaps at least partially with the orthographic projection of the first electrode via hole on the base substrate: the second electrode pattern includes a second electrode body portion and a second electrode connecting portion, and an orthotropic projection of the second electrode connecting portion on the base substrate overlaps at least partially with the orthotropic projection of the second electrode via hole on the base substrate: the first electrode connecting portion protrudes outward from the first electrode body portion, an orthographic projection of a portion of the first electrode connecting portion on the base substrate does not overlap with an orthographic projection of the first electrode body portion on the base substrate, and the orthographic projection of the second electrode connecting portion on the base substrate falls within an orthographic projection of the second electrode body portion on the base substrate.

In some exemplary embodiments of the present disclosure, an orthographic projection of the first electrode via hole on the base substrate falls within the orthographic projection of the second electrode pattern on the base substrate: and/or an orthotropic projection of the second electrode via hole on the base substrate is spaced apart from the orthographic projection of the first electrode pattern on the base substrate.

In some exemplary embodiments of the present disclosure, the display panel further includes a hole transport layer pattern and an electron transport layer pattern, and each of an orthographic projection of the hole transport layer pattern on the base substrate and an orthographic projection of the electron transport layer pattern on the base substrate is spaced apart from the orthographic projection of the second electrode via hole on the base substrate.

In some exemplary embodiments of the present disclosure, the display panel includes a plurality of control chips provided in the peripheral region, one of the plurality of control chips is configured to provide a voltage signal to at least one of the voltage signal line, the first electrode wire, the second electrode wire or the third electrode wire respectively, and another one of the plurality of control chips is configured to provide a voltage signal to at least another one of the voltage signal line, the first electrode wire, the second electrode wire or the third electrode wire respectively: or the display panel includes a control chip provided in the peripheral region, and the control chip is configured to provide a voltage signal to the voltage signal line, the first electrode wire, the second electrode wire and the third electrode wire respectively.

In some exemplary embodiments of the present disclosure, the orthographic projection of the second electrode via hole on the base substrate has a first via hole edge close to the first electrode pattern and a second via hole edge close to an edge of the second electrode pattern: a vertical distance between the first via hole edge and the edge of the first electrode pattern closest to the first via hole edge is greater than or equal to 30 microns: and/or a vertical distance between the second via hole edge and the edge of the second electrode pattern closest to the second via hole edge is greater than or equal to 30 microns.

In another aspect of the present disclosure, a display device is provided, including the display panel described above.

In another aspect of the present disclosure, a method of manufacturing a display panel is provided, including: providing a base substrate, where the base substrate includes a display region and a peripheral region located at least on a first side of the display region: forming a plurality of first electrode patterns on the base substrate, where the plurality of first electrode patterns are arranged in an array in a first direction and a second direction in the display region of the base substrate: forming a pixel defining layer on a side of a layer where the plurality of first electrode patterns are located away from the base substrate, where the pixel defining layer includes a plurality of pixel openings, and the plurality of first electrode patterns are at least partially exposed by the plurality of pixel openings respectively: forming a plurality of second electrode via holes in the display region of the base substrate: forming a plurality of light emitting layer patterns, where the plurality of light emitting layer patterns are arranged in an array in the first direction and the second direction in the display region of the base substrate, the plurality of light emitting layer patterns are at least partially located in the plurality of pixel openings respectively, orthographic projections of the plurality of light emitting layer patterns on the base substrate are spaced apart from orthographic projections of the plurality of second electrode via holes on the base substrate; forming a plurality of electrode wires on the base substrate; and forming a plurality of second electrode patterns on a side of a layer where the plurality of light emitting layer patterns are located away from the base substrate, where the plurality of second electrode patterns are arranged in an array in the first direction and the second direction in the display region of the base substrate, and orthographic projections of at least some of the plurality of the second electrode patterns on the base substrate are spaced apart from each other in the first direction and the second direction, where the plurality of electrode wires are located in at least one conductive layer between the base substrate and the layer where the plurality of second electrode patterns are located, and at least one electrode wire is electrically connected to at least one second electrode pattern through a second electrode via hole.

### BRIEF DESCRIPTION OF THE DRAWINGS

By describing in detail exemplary embodiments of the present disclosure with reference to the accompanying drawings, features and advantages of the present disclosure will become more apparent.

FIG. 1A shows a schematic diagram of a planar structure of a display panel according to some exemplary embodiments of the present disclosure:

FIG. 1B shows a schematic diagram of a cross-sectional structure of a display panel according to some exemplary embodiments of the present disclosure:

FIG. 2A shows a schematic diagram of a planar structure of a pixel unit of a display panel according to an exemplary embodiment of the present disclosure:

FIG. 2B shows a schematic diagram of a planar structure of a pixel unit of a display panel according to another exemplary embodiment of the present disclosure:

FIG. 3A shows a schematic diagram of a planar structure of electrode wires included in a display panel according to an exemplary embodiment of the present disclosure;

FIG. 3B shows a schematic diagram of a planar structure of electrode wires included in a display panel according to another exemplary embodiment of the present disclosure;

FIG. 4A shows a schematic diagram of a planar structure of a first conductive layer included in a display panel according to an exemplary embodiment of the present disclosure:

FIG. 4B shows a schematic diagram of a planar structure of a second conductive layer included in a display panel according to an exemplary embodiment of the present disclosure:

FIG. 4C shows a schematic diagram of a planar structure of a third conductive layer included in a display panel according to an exemplary embodiment of the present disclosure:

FIG. 4D shows a schematic diagram of a planar structure of a fourth conductive layer included in a display panel according to an exemplary embodiment of the present disclosure:

FIG. 4E shows a schematic diagram of a planar structure of a first electrode pattern included in a display panel according to an exemplary embodiment of the present disclosure:

FIG. 4F shows a schematic diagram of a planar structure of a second electrode pattern included in a display panel according to an exemplary embodiment of the present disclosure:

FIG. 5A shows a flowchart of a method of manufacturing a display panel according to an exemplary embodiment of the present disclosure:

FIG. 5B shows a schematic diagram of second electrode via holes formed using the method of manufacturing the display panel according to an exemplary embodiment of the present disclosure;

FIG. 5C shows a schematic diagram of an HTL material used to form a light emitting layer pattern using the method of manufacturing the display panel according to an exemplary embodiment of the present disclosure;

FIG. 5D shows a schematic diagram of an EM material used to form a light emitting layer pattern using the method of manufacturing the display panel according to an exemplary embodiment of the present disclosure:

FIG. 5E to FIG. 5F show schematic diagrams of second electrode patterns formed using the method of manufacturing the display panel according to an exemplary embodiment of the present disclosure.

### DETAILED DESCRIPTION OF EMBODIMENTS

In order to make objectives, technical solutions and advantages of the present disclosure clearer, the technical solutions of the embodiments of the present disclosure will be clearly and completely described below with reference to the accompanying drawings. Obviously, the described embodiments are just some embodiments rather than all embodiments of the present disclosure. Based on the described embodiments of the present disclosure, all additional embodiments obtained by those ordinary skilled in the art without carrying out inventive effort fall within the scope of protection of the present disclosure.

It should be noted that in the accompanying drawings, for clarity and/or description purposes, sizes and relative sizes of elements may be enlarged. Accordingly, sizes and relative sizes of elements need not to be limited to those shown in the figures. In the specification and the accompanying drawings, the same or similar reference numerals represent the same or similar components.

When an element is described as being “on”, “connected to” or “combined with” another element, the element may be directly on the another element, directly connected to the another element, or directly combined with the another element, or an intermediate element may be provided. However, when an element is described as being “directly on”, “directly connected to” or “directly combined with” another element, no intermediate element is provided. Other terms and/or expressions used to describe a relationship between elements, such as “between” and “directly between”, “adjacent to” and “directly adjacent to”, “on” and “directly on”, etc., should be interpreted in a similar manner. Moreover, the term “connection” may refer to a physical connection, an electrical connection, a communication connection, and/or a fluid connection. In addition, X-axis, Y-axis and Z-axis are not limited to three axes of a rectangular coordinate system, and may be interpreted in a broader meaning. For example, the X-axis, the Y-axis and the Z-axis may be perpendicular to each other, or may represent different directions that are not perpendicular to each other. For the objective of the present disclosure, “at least one of X, Y or Z” and “at least one selected from a group consisting of X, Y and Z” may be interpreted as only X, only Y, only Z, or any combination of two or more of X, Y and Z, such as XYZ, XYY, YZ and ZZ. As used herein, the term “and/or” includes any and all combinations of one or more of the listed related items.

It should be noted that although the terms “first”, “second”, etc. may be used herein to describe various components, members, elements, regions, layers and/or portions, these components, members, elements, regions, layers and/or portions should not be limited by these terms. Rather, these terms are used to distinguish one component, member, element, region, layer and/or portion from another one. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “above”, “below”, “left”, “right”, may be used herein to describe a relationship between one element or feature and another element or feature as shown in the figures. It should be understood that the spatial relationship terms are intended to cover other different orientations of a device in use or operation in addition to the orientation described in the figures. For example, if the device in the figures is turned upside down, an element or feature described as being “below” or “under” another element or feature will be oriented “above” or “on” the another element or feature.

Those skilled in the art should understand that herein, unless otherwise specified, the expression “height” or “thickness” refers to a size in a direction perpendicular to a surface of each film layer arranged in the display panel, that is, a size in a light emitting direction of the display panel, or referred to as a size in a normal direction of a display device or a size in Z-direction in the figures.

Herein, unless otherwise specified, the expression “patterning process” generally includes steps of photoresist coating, exposure, development, etching, and photoresist stripping. The expression “one-time patterning process” means a process of forming patterned layers, components, elements and so on by using one mask.

It should be noted that the expressions “the same layer”, “arranged in the same layer” or similar expressions refer to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific patterns in the formed layer structure may be continuous or discontinuous. These specific patterns may also be at different heights or have different thicknesses.

Herein, unless otherwise specified, the expression “electrically connected” may mean that two components or elements are directly electrically connected. For example, component or element A is in direct contact with component or element B, and an electrical signal may be transmitted between the two. It may also mean that two components or elements are electrically connected through a conductive medium such as a conductive wire. For example, component or element A is electrically connected to component or element B through a conductive wire so that an electrical signal may be transmitted between the two components or elements. Alternatively, it may also mean that two components or elements are electrically connected through at least one electronic component. For example, component or element A is electrically connected to component or element B through at least one thin film transistor so that an electrical signal may be transmitted between the two components or elements.

The embodiments of the present disclosure provide at least a display panel. The display panel includes: a base substrate, including a display region and a peripheral region located at least on a first side of the display region: a plurality of first electrode patterns arranged in an array in a first direction and a second direction in the display region of the base substrate: a pixel defining layer located on a side of a layer where the plurality of first electrode patterns are located away from the base substrate, where the pixel defining layer includes a plurality of pixel openings, and the plurality of first electrode patterns are at least partially exposed by the plurality of pixel openings respectively: a plurality of light emitting layer patterns arranged in an array in the first direction and the second direction in the display region of the base substrate, where the plurality of light emitting layer patterns are at least partially located in the plurality of pixel openings respectively: a plurality of second electrode patterns located on a side of a layer where the plurality of light emitting layer patterns are located away from the base substrate, where the plurality of second electrode patterns are arranged in an array in the first direction and the second direction in the display region of the base substrate, and orthographic projections of at least some of the plurality of second electrode patterns on the base substrate are spaced apart from each other in the first direction and the second direction: and a plurality of electrode wires located in at least one conductive layer between the base substrate and a layer where the plurality of second electrode patterns are located, where at least one electrode wire is electrically connected to at least one second electrode pattern through a second electrode via hole, and an orthographic projection of the second electrode via hole on the base substrate is located in the display region.

In the display panel according to the embodiments of the present disclosure, a plurality of first electrode patterns and a plurality of second electrode patterns are provided to drive a plurality of light emitting layer patterns, a plurality of electrode wires are provided in at least one conductive layer between the base substrate and the layer where the plurality of second electrode patterns are located, and at least one electrode wire is electrically connected to at least one second electrode pattern through a second electrode via hole, so that the use of a second electrode pattern designed as a whole is avoided, and a voltage drop caused by the second electrode pattern designed as a whole may be effectively reduced. Moreover, by providing a plurality of electrode wires and connecting the electrode wires to the second electrode patterns through the second electrode via holes located in the display region, it is possible to further improve the display effect.

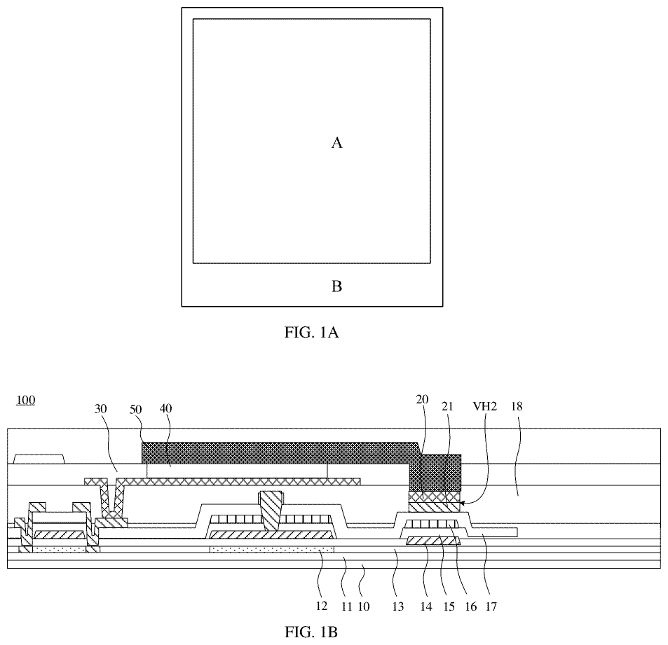

The display panel of the embodiments of the present disclosure will be described in detail below with reference to FIG. 1A to FIG. 4F.

FIG. 1A shows a schematic diagram of a planar structure of a display panel according to some exemplary embodiments of the present disclosure. FIG. 1B shows a schematic diagram of a cross-sectional structure of a display panel according to some exemplary embodiments of the present disclosure.

A display panel 100 includes: a base substrate 10, a first electrode pattern 20, a pixel defining layer 30, a light emitting layer pattern 40, a second electrode pattern 50, and a plurality of electrode wires 60.

Exemplarily, as shown in FIG. 1A, the base substrate 10 includes a display region A and a peripheral region B located on a first side of the display region. For example, the peripheral region B is located on a lower side of the display region A.

The first electrode pattern 20 may include a plurality of first electrode patterns 20 arranged in an array in a first direction X and a second direction Y in the display region A of the base substrate 10.

The pixel defining layer 30 is provided on a side of a layer where the plurality of first electrode patterns 20 are located away from the base substrate 10. The pixel defining layer 30 defines a plurality of pixel openings, and each pixel opening exposes at least part of the corresponding first electrode pattern 20. By allowing each pixel opening to expose the corresponding first electrode pattern, it is convenient to drive the light emitting layer pattern in the pixel opening to emit light or not to emit light.

The plurality of light emitting layer patterns 40 are arranged in an array in the first direction X and the second direction Y in the display region A of the base substrate 10, and the plurality of light emitting layer patterns 40 are at least partially located in the plurality of pixel openings respectively, that is, at least part of each light emitting layer pattern 40 corresponding to a pixel opening is located in the pixel opening.

The plurality of second electrode patterns 50 are located on a side of a layer where the plurality of light emitting layer patterns are located away from the base substrate 10. The plurality of second electrode patterns 50 are arranged in an array in the first direction X and the second direction Y in the display region A of the base substrate 10. Orthographic projections of at least some of the plurality of second electrode patterns 50 on the base substrate 10 are spaced apart from each other in the first direction X and the second direction Y, and different second electrode patterns 50 are spaced apart from each other in the first direction X and the second direction Y. That is, a plurality of second electrode patterns 50 may be provided, and each second electrode pattern 50 may correspond to a sub-pixel in a pixel unit or a plurality of sub-pixels in a pixel unit.

For example, the first electrode patterns 20, the pixel defining layer 30, the light emitting layer patterns 40 and the second electrode patterns 50 may be provided with the same array arrangement in the first direction X and the second direction Y, and then display units of the display panel may be formed to display corresponding images.

The plurality of electrode wires 60 are located in at least one conductive layer between the base substrate 10 and a layer where the second electrode patterns 50 are located. For example, the plurality of electrode wires 60 are located in one or more conductive layers. At least one electrode wire 60 is electrically connected to at least one second electrode pattern 50 through a second electrode via hole VH2, and an orthographic projection of the second electrode via hole VH2 on the base substrate 10 is located in the display region A. By electrically connecting the second electrode pattern 50 with the electrode wire 60, it is possible to avoid a generation of voltage drop at the second electrode pattern 50. Moreover, by providing the second electrode via hole VH2 in the display region A, it is possible to improve the display quality while avoiding the generation of voltage drop at the second electrode pattern.

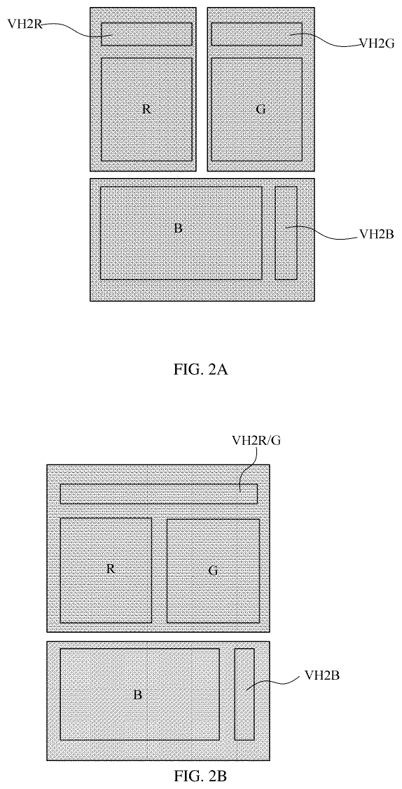

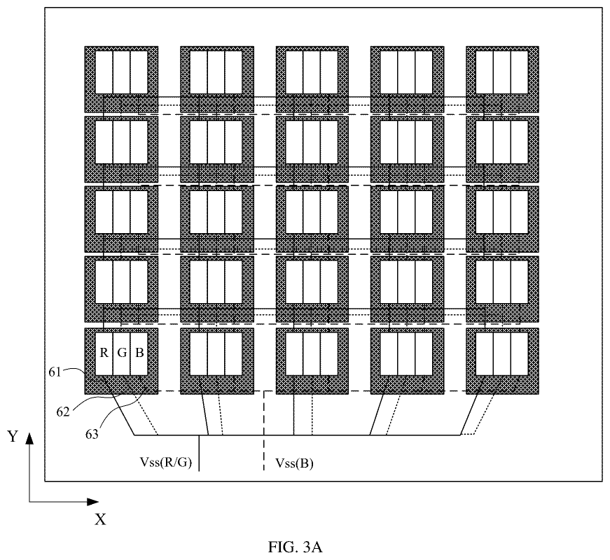

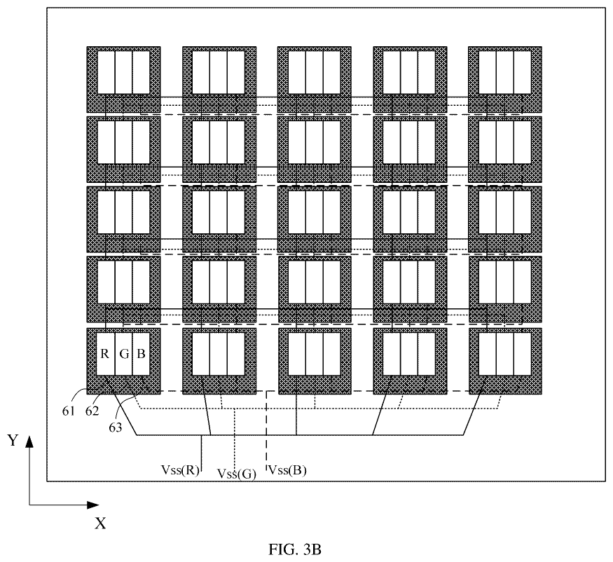

In some exemplary embodiments, the display panel 100 may include a plurality of pixel units. FIG. 2A and FIG. 2B respectively show a pixel unit. The plurality of pixel units are arranged in an array in the first direction X and the second direction Y in the display region of the base substrate, and at least one pixel unit includes a plurality of sub-pixels. For example, a pixel unit may include a red sub-pixel R, a green sub-pixel G, and a blue sub-pixel B. In other optional embodiments, for example, a pixel unit may include more or less sub-pixels, which may be set according to actual needs.

Some or all of the plurality of pixel units may further include a second electrode pattern and at least one second electrode via hole. Some or all of the pixel units may also include two or more second electrode patterns and two or more second electrode via holes.

For example, a pixel unit may include a second electrode pattern and one or more second electrode via holes.

For another example, a pixel unit may include a plurality of second electrode patterns and a plurality of electrode via holes, and the number of electrode patterns may or may not correspond to the number of electrode via holes.

In some embodiments, in a pixel unit, at least two sub-pixels share a second electrode pattern and a second electrode via hole, and the other sub-pixel has a separate second electrode pattern and a separate second electrode via hole.

In other embodiments, in a pixel unit, all of the plurality of sub-pixels of the pixel unit share a second electrode pattern and a second electrode via hole.

In still other embodiments, in a pixel unit, all of the plurality of sub-pixels of the pixel unit have respective second electrode patterns, and each sub-pixel has a corresponding second electrode via hole.

FIG. 2A shows a schematic diagram of a planar structure of a pixel unit of a

display panel according to an exemplary embodiment of the present disclosure.

As shown in FIG. 2A, a pixel unit may include three second electrode patterns (e.g., a second electrode pattern 50R, a second electrode pattern 50G, and a second electrode pattern 50B) and three second electrode via holes (a second electrode via hole VH2R, a second electrode via hole VH2G, and a second electrode via hole VH2B), and each sub-pixel has a corresponding second electrode pattern and a corresponding second electrode via hole.

FIG. 2B shows a schematic diagram of a planar structure of a pixel unit of a display panel according to another exemplary embodiment of the present disclosure.

As shown in FIG. 2B, a pixel unit may include two second electrode patterns (a second electrode pattern 50R/G and a second electrode pattern 50B) and two second electrode via holes (a second electrode via hole VH2R/G and a second electrode via hole VH2B). The red sub-pixel R and the green sub-pixel G share the same second electrode pattern and the same second electrode via hole, and the blue sub-pixel B has another second electrode pattern and another second electrode via hole.

As shown in FIG. 3A, the pixel unit includes a first sub-pixel R, a second sub-pixel G and a third sub-pixel B, and the plurality of electrode wires include a first electrode wire 61, a second electrode wire 62 and a third electrode wire 63. The shared second electrode pattern is electrically connected to the first electrode wire 61 and the second electrode wire 62 through the shared second electrode via hole. The second electrode pattern of the other sub-pixel is electrically connected to the third electrode wire 63 through the separate second electrode via hole.

In the pixel unit shown in FIG. 3A and FIG. 2B, the second electrode pattern is connected to the same voltage signal, such as Vss (R/G), through the first electrode wire 61 and the second electrode wire 62, and the second electrode pattern of the other sub-pixel is connected to a different voltage signal, such as Vss (B), through the third electrode wire 63.

FIG. 3B shows a schematic diagram of a planar structure of electrode wires included in a display panel according to another exemplary embodiment of the present disclosure.

As shown in FIG. 3B, each pixel unit includes a first sub-pixel R, a second sub-pixel G and a third sub-pixel B, and the plurality of electrode wires include a first electrode wire 61, a second electrode wire 62 and a third electrode wire 63.

For example, the second electrode pattern of the first sub-pixel is electrically connected to the first electrode wire through a second electrode via hole, the second electrode pattern of the second sub-pixel is electrically connected to the second electrode wire through a second electrode via hole, and the second electrode pattern of the third sub-pixel is electrically connected to the third electrode wire through a second electrode via hole.

At least two of the first electrode wire, the second electrode wire or the third electrode wire are connected to different voltage signals. For example, the first sub-pixel R is connected to a voltage signal Vss(R) through the first electrode wire, the second sub-pixel G is connected to a voltage signal Vss(G) through the second electrode wire, and the third sub-pixel B is connected to a voltage signal Vss(B) through the third electrode wire. That is, each second electrode pattern corresponding to a sub-pixel in the pixel unit is connected to a different electrode wire through the corresponding second electrode via hole. Since the sub-pixels correspond to different electrode patterns, the light emission of different sub-pixels may correspond to different display effects of the display panel. By connecting each second electrode pattern corresponding to a sub-pixel to a different electrode wire through the corresponding second electrode via hole, it is possible to adjust electrical signals for different sub-pixels, so that the display uniformity of the display panel may be further improved.

In another optional embodiment of the present disclosure, each pixel unit may include a first sub-pixel, a second sub-pixel and a third sub-pixel, and the electrode wire corresponding to the pixel unit may include a first electrode wire, a second electrode wire and a third electrode wire. The shared second electrode pattern is electrically connected to the first electrode wire, the second electrode wire and the third electrode wire through the shared second electrode via hole. The first electrode wire, the second electrode wire and the third electrode wire are connected to the same voltage signal. That is, the sub-pixels of each pixel unit share the same second electrode pattern and the same second electrode via hole, and each sub-pixel is connected to the same voltage signal. By providing a plurality of electrode wires, it is possible to reduce a voltage drop of a voltage signal in a transmission process and improve the display quality of the display panel.

According to the embodiments of the present disclosure, by electrically connecting the second electrode pattern to the electrode wire through the second electrode via hole, and connecting to the corresponding voltage signal, it is possible to avoid a voltage drop caused by a transmission of the voltage signal in the second electrode pattern, enhance the display uniformity of the display panel, and effectively improve the display effect of the display panel.

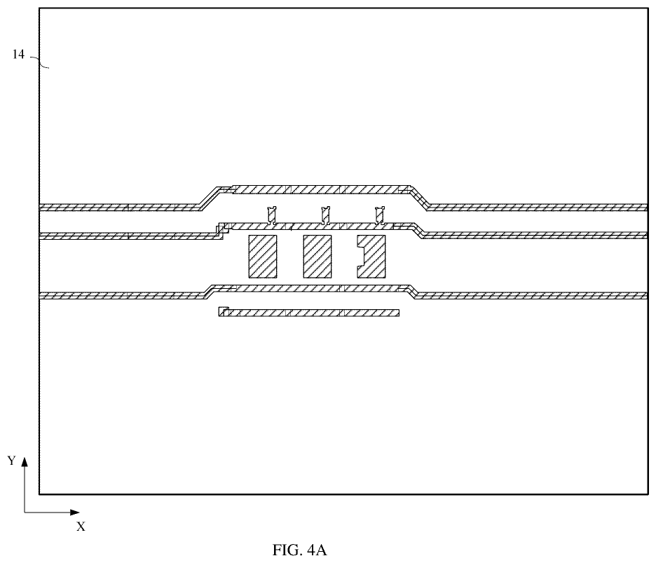

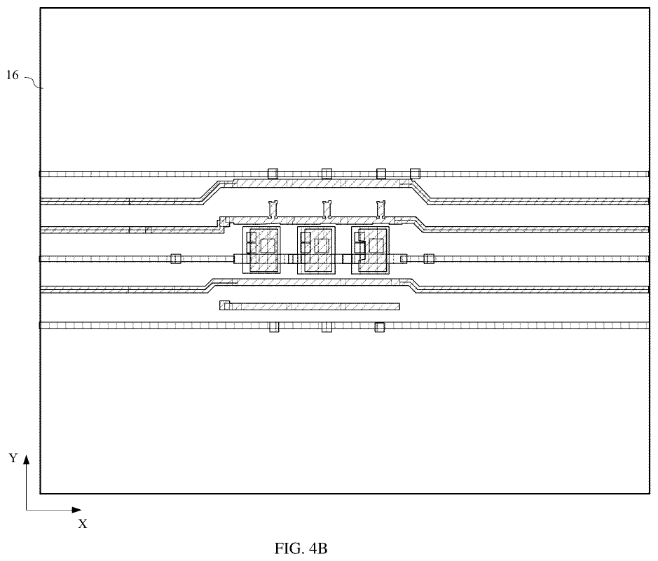

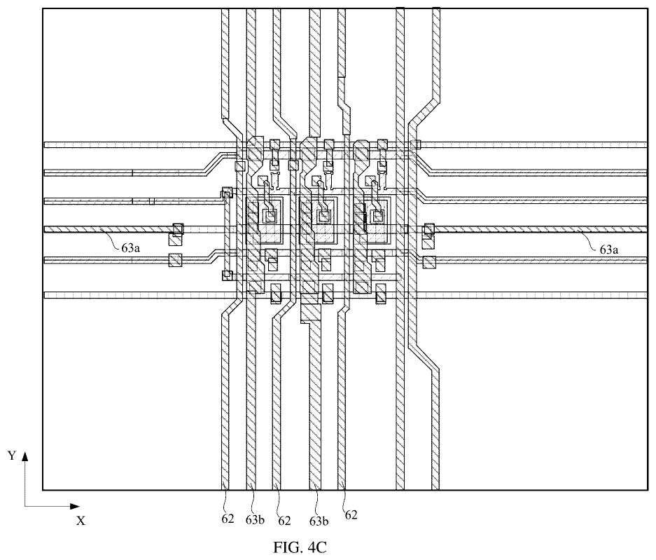

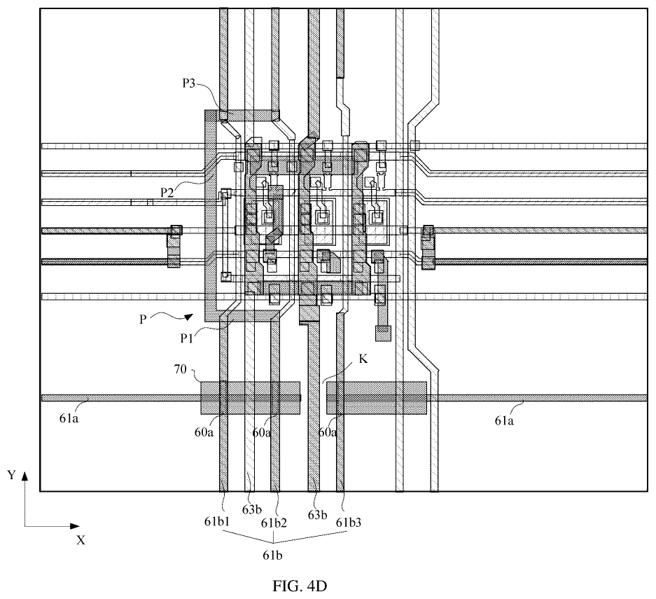

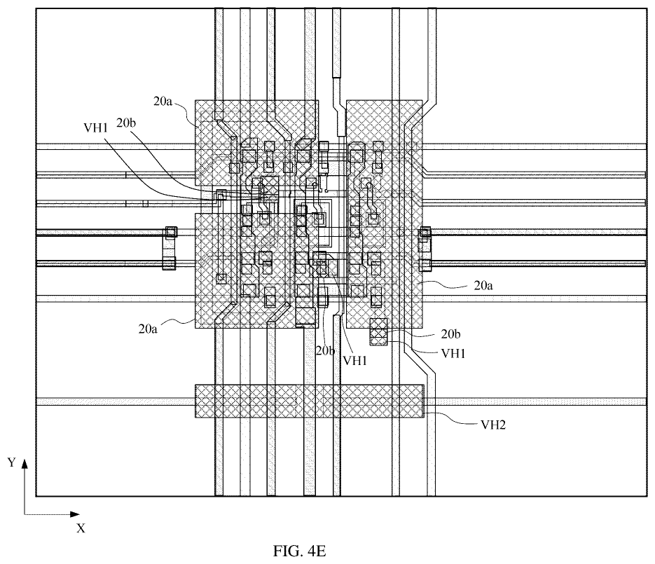

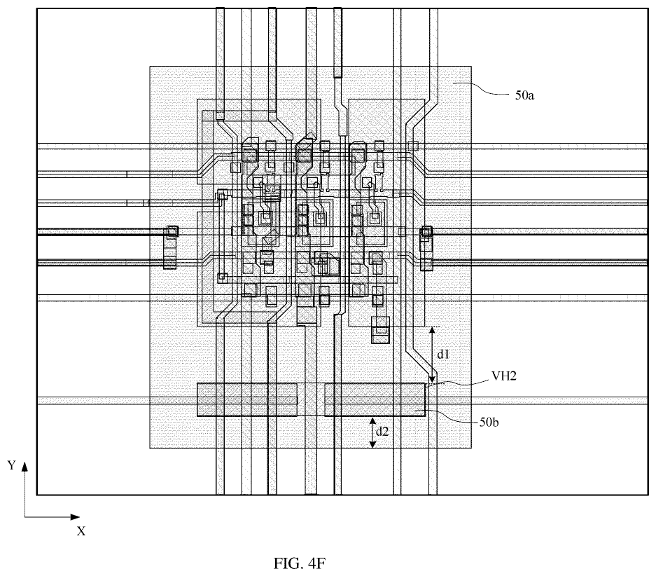

FIG. 4A shows a schematic diagram of a planar structure of a first conductive layer included in a display panel according to an exemplary embodiment of the present disclosure. FIG. 4B shows a schematic diagram of a planar structure of a second conductive layer included in a display panel according to an exemplary embodiment of the present disclosure. FIG. 4C shows a schematic diagram of a planar structure of a third conductive layer included in a display panel according to an exemplary embodiment of the present disclosure. FIG. 4D shows a schematic diagram of a planar structure of a fourth conductive layer included in a display panel according to an exemplary embodiment of the present disclosure. FIG. 4E shows a schematic diagram of a planar structure of a first electrode pattern included in a display panel according to an exemplary embodiment of the present disclosure. FIG. 4F shows a schematic diagram of a planar structure of a second electrode pattern included in a display panel according to an exemplary embodiment of the present disclosure.

As shown in FIG. 1B, the display panel includes a buffer layer 11, a semiconductor layer 12, a first insulating layer 13, a first conductive layer 14, a second insulating layer 15, a second conductive layer 16, a third insulating layer 17, a third conductive layer 21 and a fourth insulating layer 18. Specifically, the buffer layer 11 is provided on a side of the base substrate 10, the semiconductor layer 12 is provided on a side of the buffer layer 11 away from the base substrate 10, the first insulating layer 13 is provided on a side of the semiconductor layer 12 away from the base substrate 10, the first conductive layer 14 is provided on a side of the first insulating layer 13 away from the base substrate 10, the second insulating layer 15 is provided on a side of the first conductive layer 14 away from the base substrate 10, the second conductive layer 16 is provided on a side of the second insulating layer 15 away from the base substrate 10, the third insulating layer 17 is provided on a side of the second conductive layer 16 away from the base substrate 10, the third conductive layer 21 is provided on a side of the third insulating layer 17 away from the base substrate 10, and the fourth insulating layer 18 is provided on a side of the third conductive layer 21 away from the base substrate 10.

As shown in FIG. 4D, the display panel 100 further includes a fourth conductive layer 23 and a fifth insulating layer 22. The fifth insulating layer 22 is provided between the third conductive layer 21 and the fourth insulating layer 18, and the fourth conductive layer is provided between the fifth insulating layer 22 and the fourth insulating layer 18.

In some embodiments, as shown in FIG. 1B and FIG. 4A to FIG. 4F, each of an orthographic projection of the buffer layer 11 on the base substrate, an orthographic projection of the first insulating layer 13 on the base substrate, an orthographic projection of the first conductive layer 14 on the base substrate, an orthographic projection of the second insulating layer 15 on the base substrate, an orthographic projection of the second conductive layer 16 on the base substrate and an orthographic projection of the third insulating layer 17 on the base substrate overlaps partially with an orthographic projection of the second electrode via hole on the base substrate. That is, there is an overlapping portion at the projection position of the second electrode via hole to facilitate connection of wires, so as to improve a sub-pixel space utilization related to a wire arrangement.

A film layer structure in a pixel unit will be described in detail below with reference to FIG. 4A to FIG. 4F.

In the embodiments shown in FIG. 4A to FIG. 4F, a plurality of sub-pixels in a pixel unit share a second electrode pattern, and the pixel unit includes three sub-pixels.

FIG. 4A shows a schematic diagram of a planar structure of a first conductive layer 14 included in a pixel unit. FIG. 4B shows a schematic diagram of a planar structure of a second conductive layer 16 included in a pixel unit. FIG. 4C shows a schematic diagram of a planar structure of a third conductive layer 21 included in a pixel unit.

As shown in FIG. 4C and FIG. 4D, the second electrode via hole VH2 penetrates through a portion of the fourth insulating layer and a portion of the pixel defining layer.

In an optional embodiment of the present disclosure, the electrode wire 60 has a first portion 601 and a second portion 602 at the second electrode via hole VH2, the first portion of the electrode wire is located in the third conductive layer, and the second portion of the electrode wire is located in the layer where the first electrode patterns are located. Each of an orthographic projection of the buffer layer on the base substrate, an orthographic projection of the first insulating layer on the base substrate, an orthographic projection of the first conductive layer on the base substrate, an orthographic projection of the second insulating layer on the base substrate, an orthographic projection of the second conductive layer on the base substrate, an orthographic projection of the third insulating layer on the base substrate, an orthographic projection of the third conductive layer on the base substrate and an orthographic projection of the fifth insulating layer on the base substrate overlaps partially with an orthographic projection of the second electrode via hole on the base substrate.

With reference to FIG. 1B, the second electrode via hole VH2 penetrates through a portion of the fourth insulating layer 18 and a portion of the pixel defining layer 30. The electrode wire 60 has a first portion 60a and a second portion 60b at the second electrode via hole, the first portion 60a of the electrode wire is located in the fourth conductive layer, and the second portion 60b of the electrode wire is located in the layer where the first electrode patterns are located.

As shown in FIG. 4D, the first portions 60a of the electrode wire are spaced apart in the second electrode via hole VH2, that is, in the second electrode via hole VH2, the first portions 60a shown by dotted lines of the electrode wire are spaced apart in the first direction X. When the electrode wire includes three wires, the first portion 60a of each electrode wire may be spaced apart from the others.

As shown in FIG. 4D, the second portions 60b of the electrode wire are continuously provided in the second electrode via hole VH2.

As shown in FIG. 4D, the electrode wire 60 includes a first electrode sub-wire 61a and a second electrode sub-wire 61b that are located in the fourth conductive layer. A main body of the first electrode sub-wire 61a extends in the first direction X, and a main body of the second electrode sub-wire 61b extends in the second direction Y. The first electrode sub-wire 61a and the second electrode sub-wire 61b intersect at least in the second electrode via hole VH2.

As shown in FIG. 4D, the first electrode sub-wire 61a includes a plurality of first electrode sub-wires 61a, and the second electrode sub-wire 61b includes a plurality of second electrode sub-wires 61b, such as a second electrode sub-wire 61b1 corresponding to the first sub-pixel, a second electrode sub-wire 61b2 corresponding to the second sub-pixel, and a second electrode sub-wire 61b3 corresponding to the third sub-pixel.

As shown in FIG. 4C and FIG. 4D, the display panel further includes a data signal line 62 used to provide a data signal to the pixel unit. The data signal line 62 is located in the third conductive layer, and a main body of the data signal line 62 extends in the second direction Y. An orthographic projection of the second electrode sub-wire 61b on the base substrate overlaps at least partially with an orthographic projection of the data signal line 62 on the base substrate. Exemplarily, three data signal lines 62 are provided, and the orthographic projection of each data signal line 62 on the base substrate overlaps partially with the orthographic projection of each second electrode sub-wire 61b on the base substrate.

As shown in FIG. 4C, the display panel further includes a voltage signal line used to provide a voltage signal to the first electrode pattern of the pixel unit. The voltage signal line includes a first voltage signal sub-line 63a and a second voltage signal sub-line 63b. A main body of the first voltage signal sub-line 63a extends in the first direction X, and a main body of the second voltage signal sub-line 63b extends in the second direction Y.

The display panel includes a plurality of second voltage signal sub-lines 63b. At least one second voltage signal sub-line 63b is located in the third conductive layer, and at least another second voltage signal sub-line 63b is located in the fourth conductive layer. As shown in FIG. 4C and FIG. 4D, the second voltage signal sub-line 63b located in the third conductive layer and the second voltage signal sub-line 63b located in the fourth conductive layer have an overlapping portion on the base substrate.

As shown in FIG. 4D, an orthographic projection of the at least one second voltage signal sub-line in the third conductive layer on the base substrate and an orthographic projection of the second electrode sub-wire on the base substrate are spaced apart at least in the second electrode via hole.

An orthographic projection of the at least another second voltage signal sub-line 63b in the fourth conductive layer on the base substrate is spaced apart from the orthographic projection of the second electrode sub-wire 61b on the base substrate.

As shown in FIG. 4C and FIG. 4D, the orthotropic projection of the second voltage signal sub-line 63b on the based substrate is spaced apart from the orthographic projection of the second electrode sub-wire 61b on the base substrate. For example, the orthographic projections of the second voltage signal sub-wires 63b on the base substrate are respectively located between the orthotropic projections of adjacent second electrode wires 61b on the base substrate, for example, between the orthographic projection of the second electrode sub-wire 61b1 corresponding to the first sub-pixel on the base substrate and the orthographic projection of the second electrode sub-wire 61b2 corresponding to the second sub-pixel on the base substrate, and between the orthographic projection of the second electrode sub-wire 61b2 corresponding to the second sub-pixel on the base substrate and the orthographic projection of the second electrode sub-wire 61b3 corresponding to the third sub-pixel on the base substrate. By spacing the wires, it is possible to fully utilize a space to achieve a reasonable arrangement of the wires, so as to improve a space utilization and avoid a large pixel unit in the display panel.

Exemplarily, the at least another second voltage signal sub-line 63b located in the fourth conductive layer extends through a gap formed between the first portions of the electrode wire in the second electrode via hole. As shown in FIG. 4D, a gap K is formed between the first portions of the electrode wire in the fourth conductive layer in the second electrode via hole, and the second voltage signal sub-line 63b in the fourth conductive layer extends in the second direction Y and passes through the gap K.

The display panel includes a plurality of second electrode sub-wires. At least one second electrode sub-wire includes a winding portion, and the at least one second electrode sub-wire extends through a region where the first electrode pattern is located through the winding portion: and at least another second electrode sub-wire is disconnected at the region where the first electrode pattern is located.

As shown in FIG. 4D, the second electrode wire includes a second electrode sub-wire 61b1 corresponding to the first sub-pixel, a second electrode sub-wire 61b2 corresponding to the second sub-pixel, and a second electrode sub-wire 61b3 corresponding to the third sub-pixel.

The second electrode sub-wire 61b1 corresponding to the first sub-pixel includes a winding portion P, by means of which the second electrode sub-wire 61b1 extends through the region where the first electrode pattern is located. That is, the second electrode sub-wire 61b1 extends in the second direction and passes through the region where the first electrode pattern is located along an edge of the region where the first electrode pattern is located.

The second electrode sub-wire 61b3 corresponding to the third sub-pixel is disconnected at the region where the first electrode pattern is located. As shown in FIG. 4D, the second electrode sub-wire 61b3 is disconnected at the region where the first electrode pattern is located, so as to avoid problems of an increase in manufacturing process cost and a decrease in yield caused by complex wires passing through the region where the first electrode pattern is located.

According to the embodiments of the present disclosure, by providing the winding portion P, it is possible to avoid problems of complex manufacturing process and increased cost caused by complexity of internal wires. Moreover, the winding portion P extends through the region where the first electrode pattern is located, so that an increase in a pixel unit size caused by the winding design may be avoided in the pixel unit in the display panel.

As shown in FIG. 4D, the winding portion P includes a first winding sub-portion P1, a second winding sub-portion P2, and a third winding sub-portion P3. The first winding sub-portion P1 and the third winding sub-portion P3 extend in the first direction X, and the second winding sub-portion P2 extends in the second direction Y.

Exemplarily, for a second electrode sub-wire 61b, an orthographic projection of the second winding sub-portion P2 in the region where the first electrode pattern is located on the base substrate is closer to an edge of the first electrode pattern than an orthotropic projection of a portion of the second electrode sub-wire 61b outside the region where the first electrode pattern is located on the base substrate. That is, the second winding sub-portion P2 is closer to a periphery of the first electrode pattern than the second electrode sub-wire, so as to better achieve a winding function to avoid the problems of complex manufacturing process and increased manufacturing cost caused by complexity of wires in the region where the first electrode pattern is located.

As shown in FIG. 4E, the first electrode pattern 20 includes a first electrode body portion 20a and a first electrode connecting portion 20b, and the display panel further includes a first electrode via hole VH1. An orthographic projection of the first electrode connecting portion 20b on the base substrate overlaps at least partially with an orthographic projection of the first electrode via hole VH1 on the base substrate.

As shown in FIG. 4F, the second electrode pattern 50 includes a second electrode body portion 50a and a second electrode connecting portion 50b. An orthographic projection of the second electrode connecting portion 50b on the base substrate overlaps at least partially with the orthographic projection of the second electrode via hole VH2 on the base substrate.

As shown in FIG. 4E, the first electrode connecting portion 20b protrudes outward from the first electrode body portion 20a, that is, towards a periphery of the first electrode body portion 20a. An orthographic projection of a portion of the first electrode connecting portion 20b on the base substrate does not overlap with an orthographic projection of the first electrode body portion 20a on the base substrate, that is, the first electrode connecting portion 20b is located on an outer side of the first electrode body portion 20a.

As shown in FIG. 4F, an orthographic projection of the second electrode connecting portion 50b on the base substrate falls within an orthographic projection of the second electrode body portion 50a on the base substrate. The orthographic projection of the second electrode connecting portion 50b on the base substrate and the orthographic projection of the electrode body portion 50a on the base substrate have an overlapping portion.

Exemplarily, the orthographic projection of the first electrode via hole VH1 on the base substrate falls within the orthographic projection of the second electrode pattern on the base substrate, that is, the orthographic projection of the first electrode via hole VH1 on the base substrate and the orthographic projection of the second electrode pattern on the base substrate have an overlapping portion.

Exemplarily, the orthotropic projection of the second electrode via hole VH2 on the base substrate is spaced apart from the orthographic projection of the first electrode pattern on the base substrate, for example, in the second direction Y. By spacing the first electrode pattern from the second electrode via hole VH2, it is possible to avoid affecting the electrode wires in the second electrode via hole during the formation of the first electrode pattern.

The light emitting layer pattern of the display panel includes a plurality of layers, such as a hole injection layer HIL, a hole transport layer HTL, a light emitting layer EML, and an electron transport layer ETL, etc.

Exemplarily, the display panel further includes a hole transport layer pattern HTL and an electron transport layer pattern ETL. Each of an orthographic projection of the hole transport layer pattern on the base substrate and an orthographic projection of the electron transport layer pattern on the base substrate is spaced apart from the orthotropic projection of the second electrode via hole on the base substrate.

By spacing the orthographic projections of the above-mentioned patterns on the base substrate from the orthographic projection of the second electrode via hole on the base substrate, it is possible to effectively avoid a low product yield caused by a process accuracy of the formation of the patterns and the second electrode via hole.

As shown in FIG. 4C to FIG. 4F, the display panel includes the first electrode wires, the second electrode wires, the third electrode wires, and the voltage signal lines corresponding to the pixel units in the second direction Y. By controlling the electrical signal of each wire, it is possible to control the sub-pixels in the pixel units, so as to achieve a display function of the display panel.

Exemplarily, the display panel includes a plurality of control chips provided in the peripheral region B shown in FIG. 1A. One of the plurality of control chips is used to provide a voltage signal to at least one of the voltage signal line, the first electrode wire, the second electrode wire or the third electrode wire respectively, and another one of the plurality of control chips is used to provide a voltage signal to at least another one of the voltage signal line, the first electrode wire, the second electrode wire or the third electrode wire respectively.

For example, the display panel may include two control chips jointly providing five voltage control signals, such as AVDD/VDD/VSS (R)/VSS (G)/VSS (G), which are respectively input into the voltage signal line, the first electrode wire, the second electrode wire and the third electrode wire.

The display panel may include one control chip provided in the peripheral region. That control chip is used to provide voltage signals to the voltage signal line, the first electrode wire, the second electrode wire and the third electrode wire respectively.

For another example, it is possible to use one control chip, which may be a customized unconventional chip. That control chip may provide five control signals respectively input into the voltage signal line, the first electrode wire, the second electrode wire and the third electrode wire.

In some exemplary embodiments, the orthographic projection of the second electrode via hole VH2 on the base substrate has a first via hole edge and a second via hole edge. The first via hole edge is close to the first electrode pattern, and the second via hole edge is close to an edge of the second electrode pattern.

As shown in FIG. 4F, a vertical distance between the first via hole edge and an edge of the first electrode pattern close to the first via hole edge is d1, and a vertical distance between the second via hole edge and an edge of the second electrode pattern close to the second via hole edge is d2. The vertical distance d1 between the first via hole edge and the edge of the first electrode pattern closest to the first via hole edge is greater than or equal to 30 microns. The vertical distance d2 between the second via hole edge and the edge of the second electrode pattern closest to the second via hole edge is greater than or equal to 30 microns.

By forming the above-mentioned distances, it is possible to avoid a low product yield caused by entering of materials used for forming the first electrode pattern, the light emitting layer pattern and the second electrode pattern into the second electrode via hole due to a process accuracy during the formation of these patterns.

In another aspect of the embodiments of the present disclosure, a display device including the above-mentioned display panel is provided. For example, a film layer structure of the display panel included in the display device may refer to the description of the aforementioned embodiments, which will not be repeated here.

The display device may include any apparatus or product having a display function. For example, the display device may be a smart phone, a mobile phone, an e-book reader, a desktop personal computer (PC), a laptop PC, a netbook PC, a personal digital assistant (PDA), a portable multimedia player (PMP), a digital audio player, a mobile medical apparatus, a camera, a wearable apparatus (such as head-mounted apparatus, electronic clothing, electronic bracelet, electronic necklace, electronic accessory, electronic tattoo, or smart watch), a television, etc.

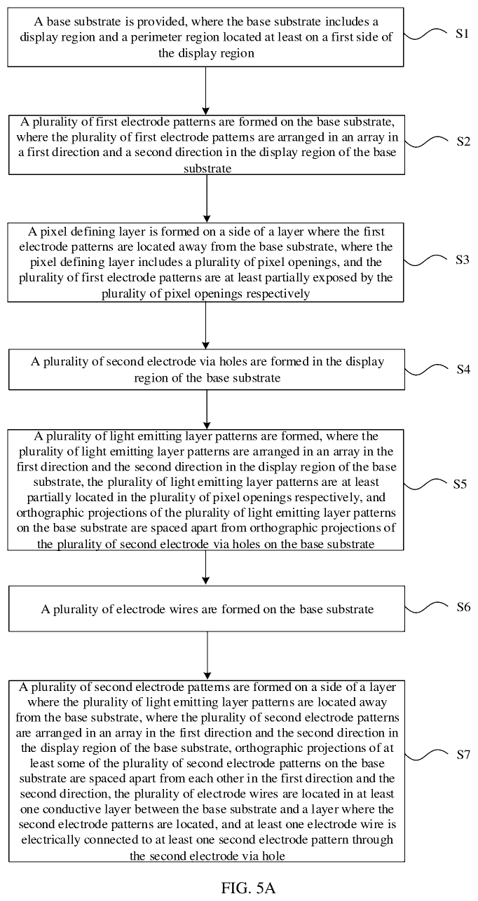

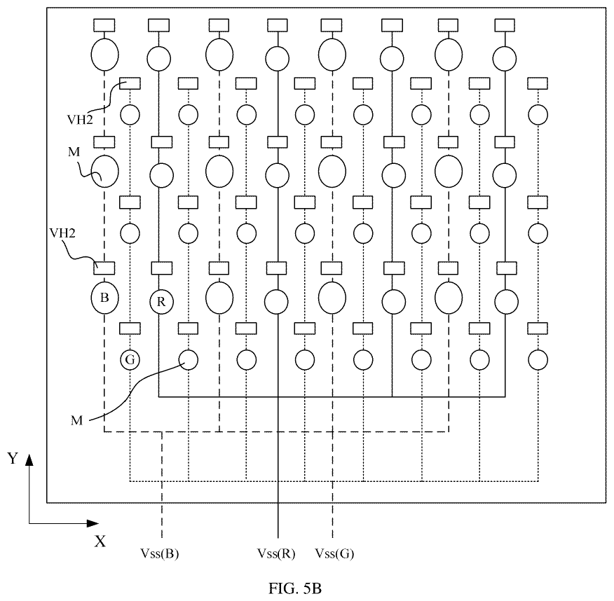

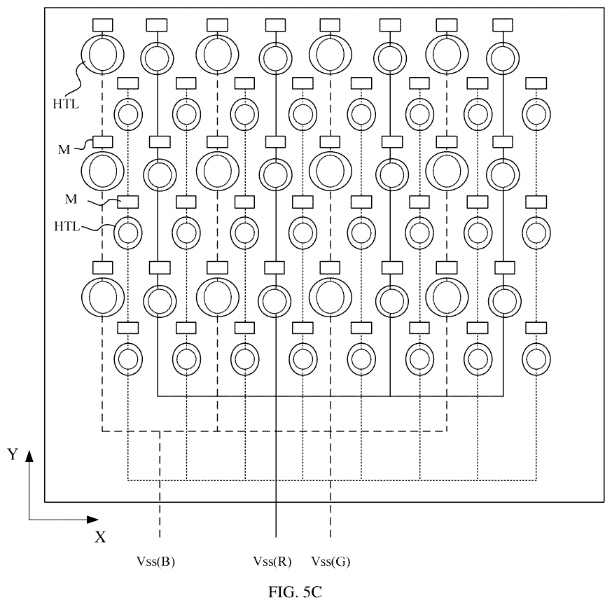

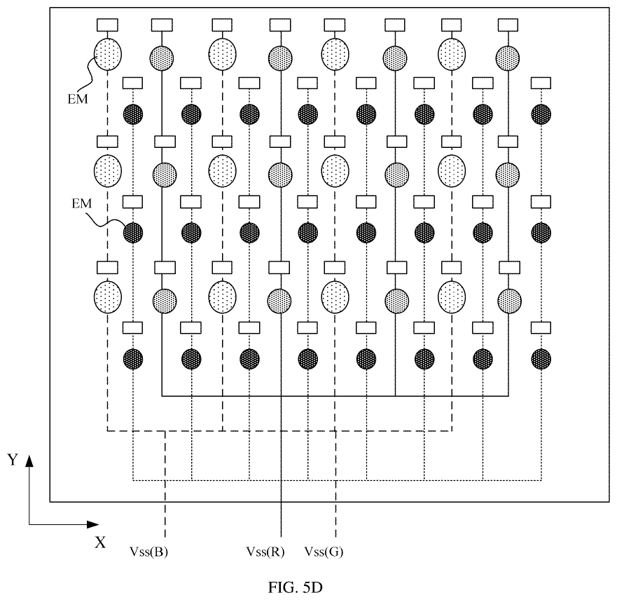

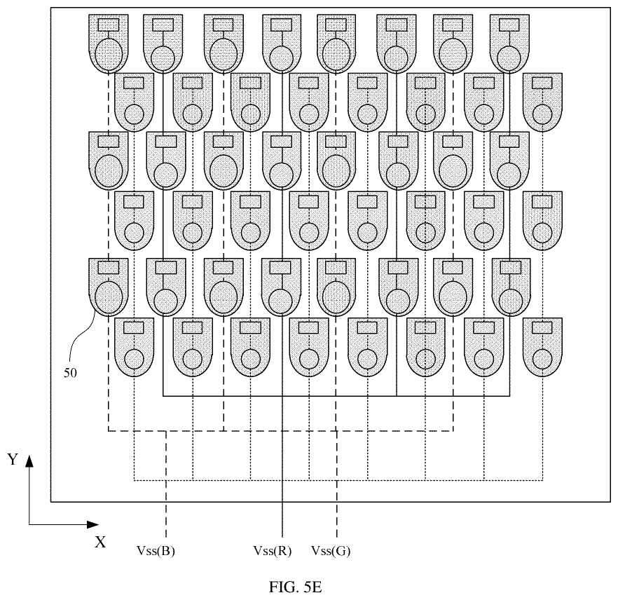

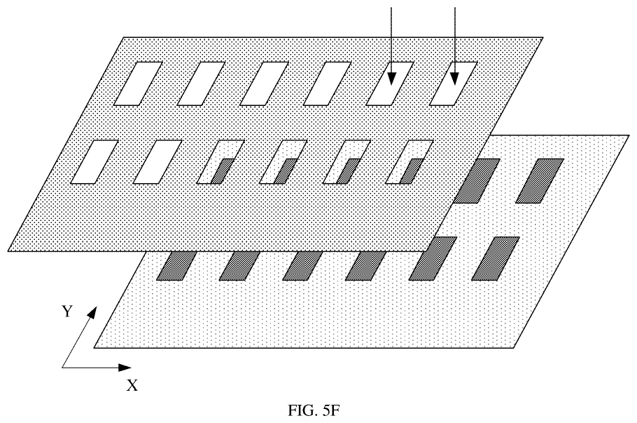

FIG. 5A shows a flowchart of a method of manufacturing a display panel according to an exemplary embodiment of the present disclosure. FIG. 5B shows a schematic diagram of second electrode via holes formed using the method of manufacturing the display panel according to an exemplary embodiment of the present disclosure. FIG. 5C shows a schematic diagram of an HTL material used to form a light emitting layer pattern using the method of manufacturing the display panel according to an exemplary embodiment of the present disclosure. FIG. 5D shows a schematic diagram of an EM material used to form a light emitting layer pattern using the method of manufacturing the display panel according to an exemplary embodiment of the present disclosure. FIG. 5E to FIG. 5F show schematic diagrams of second electrode patterns formed using the method of manufacturing the display panel according to an exemplary embodiment of the present disclosure.

In another aspect of the embodiments of the present disclosure, a method of manufacturing a display panel is further provided.

The manufacturing method includes operation S1 to operation S7, as shown in FIG. 5A.

In operation S1, a base substrate is provided, where the base substrate includes a display region and a perimeter region located at least on a first side of the display region.

In operation S2, a plurality of first electrode patterns are formed on the base substrate, where the plurality of first electrode patterns are arranged in an array in a first direction and a second direction in the display region of the base substrate.

In operation S3, a pixel defining layer is formed on a side of a layer where the first electrode patterns are located away from the base substrate, where the pixel defining layer includes a plurality of pixel openings, and the plurality of first electrode patterns are at least partially exposed by the plurality of pixel openings respectively.

In operation S4, a plurality of second electrode via holes are formed in the display region of the base substrate.

As shown in FIG. 5B, after a plurality of pixel openings M are formed in the pixel defining layer of the base substrate, a size of the formed pixel opening M may be adjusted according to design needs. A second electrode via hole VH2 is formed at a position corresponding to each pixel opening M, so that each electrode via hole VH2 corresponds to the pixel opening M.

In operation S5, a plurality of light emitting layer patterns are formed, where the plurality of light emitting layer patterns are arranged in an array in the first direction X and the second direction Y in the display region of the base substrate, the plurality of light emitting layer patterns are at least partially located in the plurality of pixel openings respectively, and orthographic projections of the plurality of light emitting layer patterns on the base substrate are spaced apart from orthographic projections of the plurality of second electrode via holes on the base substrate.

As shown in FIG. 5C, a light emitting layer pattern continues to be formed in the pixel opening, where materials that form the light emitting layer pattern include a hole transport layer (HTL) material, an electron transport layer (ETL) material and a light emitting layer (EML) material, etc. The HTL material is formed in the pixel opening by evaporation. Specifically, a region where the HTL material is formed by evaporation is larger than the pixel opening and avoids a region where the second electrode via hole is located, so that the display quality of the display panel may be ensured. Then, as shown in FIG. 5D, different EM materials are evaporated for different sub-pixels, so that the sub-pixels may emit different colors of light. Then, the ETL material continues to be formed by evaporation on an upper side of the EM material. Similarly, when the ETL material is formed by evaporation, the evaporation is performed in the pixel opening and avoids the region where the second electrode via hole is located.

In operation S6, a plurality of electrode wires are formed on the base substrate.

In operation S7, a plurality of second electrode patterns are formed on a side of a layer where the plurality of light emitting layer patterns are located away from the base substrate, where the plurality of second electrode patterns are arranged in an array in the first direction and the second direction in the display region of the base substrate, orthographic projections of at least some of the plurality of second electrode patterns on the base substrate are spaced apart from each other in the first direction and the second direction, the plurality of electrode wires are located in at least one conductive layer between the base substrate and a layer where the plurality of second electrode patterns are located, and at least one electrode wire is electrically connected to at least one second electrode pattern through the second electrode via hole.

As shown in FIG. 5E and FIG. 5F, the second electrode pattern is formed by evaporation in an upper region of the pixel opening and an upper region of the second electrode via hole, and the second electrode pattern covers the sub-pixels of each pixel unit. As shown in FIG. 5F, a mask is on an upper side, and the second electrode pattern formed is on a lower side.

It should be understood that the display device according to the embodiments of the present disclosure has all the features and advantages of the above-mentioned display substrate (such as a first substrate) and display panel, and details may refer to the above descriptions.

Although some embodiments of the general technical concept of the present disclosure have been illustrated and described, it should be understood by those ordinary skilled in the art that those embodiments may be changed without departing from the principle and spirit of the general technical concept of the present disclosure. The scope of the present disclosure is defined by the claims and their equivalents.

1. A display panel, comprising:
a base substrate, comprising a display region and a peripheral region located at least on a first side of the display region;
a plurality of first electrode patterns, wherein the plurality of first electrode patterns are arranged in an array in a first direction and a second direction in the display region of the base substrate;
a pixel defining layer located on a side of a layer where the plurality of first electrode patterns are located away from the base substrate, wherein the pixel defining layer comprises a plurality of pixel openings, and the plurality of first electrode patterns are at least partially exposed by the plurality of pixel openings respectively;
a plurality of light emitting layer patterns arranged in an array in the first direction and the second direction in the display region of the base substrate, wherein the plurality of light emitting layer patterns are at least partially located in the plurality of pixel openings respectively;
a plurality of second electrode patterns located on a side of a layer where the plurality of light emitting layer patterns are located away from the base substrate, wherein the plurality of second electrode patterns are arranged in an array in the first direction and the second direction in the display region of the base substrate, and orthographic projections of at least some of the plurality of second electrode patterns on the base substrate are spaced apart from each other in the first direction and the second direction; and
a plurality of electrode wires located in at least one conductive layer between the base substrate and a layer where the plurality of second electrode patterns are located, wherein at least one electrode wire is electrically connected to at least one second electrode pattern through a second electrode via hole,
wherein an orthographic projection of the second electrode via hole on the base substrate is located in the display region.

2. The display panel according to claim 1, wherein the display panel comprises a plurality of pixel units arranged in an array in the first direction and the second direction in the display region of the base substrate, and at least one pixel unit comprises a plurality of sub-pixels;
at least one pixel unit comprises at least one second electrode pattern and at least one second electrode via hole; and/or at least one pixel unit comprises at least two second electrode patterns and at least two second electrode via holes.

3. The display panel according to claim 2, wherein in a same pixel unit, at least two sub-pixels share a second electrode pattern and a second electrode via hole, and the other sub-pixel has a separate second electrode pattern and a separate second electrode via hole.

4. The display panel according to claim 2, wherein the plurality of sub-pixels of at least one pixel unit share a second electrode pattern and a second electrode via hole.

5. The display panel according to claim 2, wherein the plurality of sub-pixels of at least one pixel unit have respective second electrode patterns and respective second electrode via holes.

6. The display panel according to claim 3, wherein at least one pixel unit comprises a first sub-pixel, a second sub-pixel and a third sub-pixel, and the plurality of electrode wires comprise a first electrode wire, a second electrode wire and a third electrode wire;
the shared second electrode pattern is electrically connected to the first electrode wire and the second electrode wire through the shared second electrode via hole; the second electrode pattern of the other sub-pixel is electrically connected to the third electrode wire through the separate second electrode via hole;
the first electrode wire and the second electrode wire are connected to a same voltage signal, and the first electrode wire and the third electrode wire are connected to different voltage signals.

7. The display panel according to claim 5, wherein the plurality of sub-pixels of at least one pixel unit comprise a first sub-pixel, a second sub-pixel and a third sub-pixel, and the plurality of electrode wires comprise a first electrode wire, a second electrode wire and a third electrode wire;
the second electrode pattern of the first sub-pixel is electrically connected to the first electrode wire through the second electrode via hole, the second electrode pattern of the second sub-pixel is electrically connected to the second electrode wire through the second electrode via hole, and the second electrode pattern of the third sub-pixel is electrically connected to the third electrode wire through the second electrode via hole;
at least two of the first electrode wire, the second electrode wire and the third electrode wire are connected to different voltage signals.

8. The display panel according to claim 4, wherein at least one pixel unit comprises a first sub-pixel, a second sub-pixel and a third sub-pixel, and the plurality of electrode wires comprise a first electrode wire, a second electrode wire and a third electrode wire;
the shared second electrode pattern is electrically connected to the first electrode wire, the second electrode wire and the third electrode wire through the shared second electrode via hole;
the first electrode wire, the second electrode wire and the third electrode wire are connected to a same voltage signal.

9. The display panel according to claim 1, wherein the display panel comprises:
a buffer layer provided on the base substrate;
a semiconductor layer provided on a side of the buffer layer away from the base substrate;
a first insulating layer provided on a side of the semiconductor layer away from the base substrate;
a first conductive layer provided on a side of the first insulating layer away from the base substrate;
a second insulating layer provided on a side of the first conductive layer away from the base substrate;
a second conductive layer provided on a side of the second insulating layer away from the base substrate;
a third insulating layer provided on a side of the second conductive layer away from the base substrate;
a third conductive layer provided on a side of the third insulating layer away from the base substrate; and
a fourth insulating layer provided on a side of the third conductive layer away from the base substrate,
wherein each of an orthographic projection of the buffer layer on the base substrate, an orthographic projection of the first insulating layer on the base substrate, an orthographic projection of the first conductive layer on the base substrate, an orthographic projection of the second insulating layer on the base substrate, an orthographic projection of the second conductive layer on the base substrate and an orthographic projection of the third insulating layer on the base substrate overlaps partially with an orthographic projection of the second electrode via hole on the base substrate.

10. The display panel according to claim 9, wherein the second electrode via hole penetrates through a portion of the fourth insulating layer and a portion of the pixel defining layer; and
the electrode wire has a first portion and a second portion at the second electrode via hole, the first portion of the electrode wire is located in the third conductive layer, and the second portion of the electrode wire is located in the layer where the first electrode patterns are located.

11. The display panel according to claim 9, wherein the display panel further comprises:
a fifth insulating layer provided between the third conductive layer and the fourth insulating layer; and
a fourth conductive layer provided between the fifth insulating layer and the fourth insulating layer,
wherein each of the orthographic projection of the buffer layer on the base substrate, the orthographic projection of the first insulating layer on the base substrate, the orthographic projection of the first conductive layer on the base substrate, the orthographic projection of the second insulating layer on the base substrate, the orthographic projection of the second conductive layer on the base substrate, the orthographic projection of the third insulating layer on the base substrate, an orthographic projection of the third conductive layer on the base substrate and an orthographic projection of the fifth insulating layer on the base substrate overlaps partially with the orthographic projection of the second electrode via hole on the base substrate.

12. The display panel according to claim 11, wherein the second electrode via hole penetrates through a portion of the fourth insulating layer and a portion of the pixel defining layer; and
the electrode wire has a first portion and a second portion at the second electrode via hole, the first portion of the electrode wire is located in the fourth conductive layer, and the second portion of the electrode wire is located in the layer where the first electrode patterns are located.

13. The display panel according to claim 12, wherein first portions of the electrode wires are spaced apart in the second electrode via hole, and second portions of the electrode wires are continuously arranged in the second electrode via hole.

14. The display panel according to claim 11, wherein the electrode wire comprises a first electrode sub-wire and a second electrode sub-wire in the fourth conductive layer, a main body of the first electrode sub-wire extends in the first direction, and a main body of the second electrode sub-wire extends in the second direction;
the first electrode sub-wire and the second electrode sub-wire intersect at least in the second electrode via hole.

15. The display panel according to claim 14, wherein the display panel further comprises a data signal line configured to provide a data signal to the pixel unit, the data signal line is located in the third conductive layer, and a main body of the data signal line extends in the second direction;
an orthographic projection of the second electrode sub-wire on the base substrate overlaps at least partially with an orthographic projection of the data signal line on the base substrate.

16. The display panel according to claim 15, wherein the display panel further comprises a voltage signal line configured to provide a voltage signal to the first electrode pattern of the pixel unit; and
the voltage signal line comprises a first voltage signal sub-line and a second voltage signal sub-line, a main body of the first voltage signal sub-line extends in the first direction, and a main body of the second voltage signal sub-line extends in the second direction.

17. The display panel according to claim 16, wherein the display panel comprises a plurality of second voltage signal sub-lines, at least one second voltage signal sub-line is located in the third conductive layer, and at least another second voltage signal sub-line is located in the fourth conductive layer;
an orthographic projection of the at least one second voltage signal sub-line in the third conductive layer on the base substrate is spaced apart from an orthographic projection of the second electrode sub-wire on the base substrate at least in the second electrode via hole, and an orthographic projection of the at least another second voltage signal sub-line in the fourth conductive layer on the base substrate is spaced apart from the orthographic projection of the second electrode sub-wire on the base substrate,
wherein the at least another second voltage signal sub-line located in the fourth conductive layer extends through a gap between first portions of the electrode wires in the second electrode via hole,
wherein the display panel comprises a plurality of second electrode sub-wires, at least one second electrode sub-wire comprises a winding portion, and the at least one second electrode sub-wire extends through a region where the first electrode pattern is located through the winding portion; and
at least another second electrode sub-wire is disconnected in the region where the first electrode pattern is located,
wherein the winding portion comprises a first winding sub-portion, a second winding sub-portion and a third winding sub-portion, the first winding sub-portion and the third winding sub-portion extend in the first direction, and the second winding sub-portion extends in the second direction;
for a same second electrode sub-wire, an orthotropic projection of the second winding sub-portion in the region where the first electrode pattern is located on the base substrate is closer to an edge of the first electrode pattern than an orthotropic projection of a portion of the second electrode sub-wire outside the region where the first electrode pattern is located on the base substrate.

18. (canceled)

19. (canceled)

20. (canceled)

21. The display panel according to claim 1, wherein the first electrode pattern comprises a first electrode body portion and a first electrode connecting portion, the display panel further comprises a first electrode via hole, and an orthographic projection of the first electrode connecting portion on the base substrate overlaps at least partially with the orthographic projection of the first electrode via hole on the base substrate;
the second electrode pattern comprises a second electrode body portion and a second electrode connecting portion, and an orthotropic projection of the second electrode connecting portion on the base substrate overlaps at least partially with the orthotropic projection of the second electrode via hole on the base substrate;
the first electrode connecting portion protrudes outward from the first electrode body portion, an orthographic projection of a portion of the first electrode connecting portion on the base substrate does not overlap with an orthographic projection of the first electrode body portion on the base substrate, and the orthographic projection of the second electrode connecting portion on the base substrate falls within an orthographic projection of the second electrode body portion on the base substrate,
wherein an orthographic projection of the first electrode via hole on the base substrate falls within the orthographic projection of the second electrode pattern on the base substrate; and/or
an orthotropic projection of the second electrode via hole on the base substrate is spaced apart from the orthographic projection of the first electrode pattern on the base substrate,
wherein the display panel further comprises a hole transport layer pattern and an electron transport layer pattern, and each of an orthographic projection of the hole transport layer pattern on the base substrate and an orthographic projection of the electron transport layer pattern on the base substrate is spaced apart from the orthographic projection of the second electrode via hole on the base substrate,
wherein the display panel comprises a plurality of control chips provided in the peripheral region, one of the plurality of control chips is configured to provide a voltage signal to at least one of the voltage signal line, the first electrode wire, the second electrode wire or the third electrode wire respectively, and another one of the plurality of control chips is configured to provide a voltage signal to at least another one of the voltage signal line, the first electrode wire, the second electrode wire or the third electrode wire respectively; or
the display panel comprises a control chip provided in the peripheral region, and the control chip is configured to provide a voltage signal to the voltage signal line, the first electrode wire, the second electrode wire and the third electrode wire respectively,
wherein the orthographic projection of the second electrode via hole on the base substrate has a first via hole edge close to the first electrode pattern and a second via hole edge close to an edge of the second electrode pattern;
a vertical distance between the first via hole edge and the edge of the first electrode pattern closest to the first via hole edge is greater than or equal to 30 microns; and/or a vertical distance between the second via hole edge and the edge of the second electrode pattern closest to the second via hole edge is greater than or equal to 30 microns.

22. (canceled)

23. (canceled)

24. (canceled)

25. (canceled)

26. A display device, comprising the display panel according to claim 1.

27. A method of manufacturing a display panel, comprising:
providing a base substrate, wherein the base substrate comprises a display region and a peripheral region located at least on a first side of the display region;
forming a plurality of first electrode patterns on the base substrate, wherein the plurality of first electrode patterns are arranged in an array in a first direction and a second direction in the display region of the base substrate;
forming a pixel defining layer on a side of a layer where the plurality of first electrode patterns are located away from the base substrate, wherein the pixel defining layer comprises a plurality of pixel openings, and the plurality of first electrode patterns are at least partially exposed by the plurality of pixel openings respectively;
forming a plurality of second electrode via holes in the display region of the base substrate;
forming a plurality of light emitting layer patterns, wherein the plurality of light emitting layer patterns are arranged in an array in the first direction and the second direction in the display region of the base substrate, the plurality of light emitting layer patterns are at least partially located in the plurality of pixel openings respectively, orthographic projections of the plurality of light emitting layer patterns on the base substrate are spaced apart from orthographic projections of the plurality of second electrode via holes on the base substrate;
forming a plurality of electrode wires on the base substrate; and
forming a plurality of second electrode patterns on a side of a layer where the plurality of light emitting layer patterns are located away from the base substrate, wherein the plurality of second electrode patterns are arranged in an array in the first direction and the second direction in the display region of the base substrate, and orthographic projections of at least some of the plurality of the second electrode patterns on the base substrate are spaced apart from each other in the first direction and the second direction,
wherein the plurality of electrode wires are located in at least one conductive layer between the base substrate and the layer where the plurality of second electrode patterns are located, and at least one electrode wire is electrically connected to at least one second electrode pattern through a second electrode via hole.
